(19) United States
(12) Patent Application Publication
(10) Pub. No.: US 2026/0349057 A1
(43) Pub. Date: Nov. 5, 2026

(54) MAGNETIC RESONANCE SYSTEM AND HEAD COIL FOR MAGNETIC RESONANCE SYSTEM

(71) Applicant: GE Precision Healthcare LLC, Waukesha, WI (US)

(72) Inventors: Xuelian Lu, Beijing (CN); Kun Wang, Beijing (CN); Jiabin Yao, Beijing (CN); Cunli Zhang, Beijing (CN); Yulong Duan, Beijing (CN); Xiwen Zheng, Beijing (CN)

(21) Appl. No.: 19/662,154

(22) Filed: Apr. 29, 2026

(30) Foreign Application Priority Data
Apr. 30, 2025 (CN) 202510570894.6

(51) Int. Cl. G01R 33/34; G01R 33/3415

(52) U.S. Cl. CPC G01R 33/34076; G01R 33/3415

(57) ABSTRACT

Embodiments of the present application provide a head coil for a magnetic resonance system. The head coil comprises a coil support body, and a coil unit disposed on the coil support body. The coil unit comprises a first end ring and a second end ring. The centers of the first end ring and the second end ring are opposite to each other, and the inner diameter of the second end ring is less than the inner diameter of the first end ring. The coil unit further comprises a plurality of conductive portions connecting the first end ring and the second end ring, each of the conductive portions including a first extension portion extending from the first end ring along a first direction, and a second extension portion extending from the second end ring along a second direction.

### CROSS-REFERENCE TO RELATED APPLICATIONS

This application is based on and claims priority to Chinese Patent Application No. 202510570894.6, filed on Apr. 30, 2025, the entire contents of which is herein incorporated by reference.

### TECHNICAL FIELD

Embodiments of the present application relate to the technical field of medical imaging, and relate in particular to a magnetic resonance system, and a head coil for the magnetic resonance system.

### BACKGROUND

Magnetic resonance systems have been widely used in the field of medical diagnosis. Existing magnetic resonance systems generally have a main magnet, a radio frequency coil, a gradient coil, and the like. The radio frequency coil transmits a radio frequency excitation signal for exciting a scanned object to generate a magnetic resonance signal, based on which a medical image of the scanned object can be reconstructed.

Currently, radio frequency coils include transmit coils, receive coils, and transmit/receive coils capable of operating in both transmit and receive modes. A transmit coil comprises, for example, a body coil, which is disposed along a scanning cavity to surround the subject. The body coil is capable of receiving a radio frequency excitation pulse to generate a radio frequency excitation signal for exciting the whole body of the subject, and is therefore suitable for whole body imaging. The body coil can also operate in a receive mode to receive magnetic resonance signals generated by the subject.

The transmit coil may further include a local coil. When a medical image of a local body part needs to be obtained, a corresponding local coil may be used to obtain better image quality. Local coils include, for example, head coils, which can also operate in a receive mode.

Either the body coil or the local coil may be selected, by means of a switching circuit, to receive the radio frequency excitation pulse. When the local coil is selected, the body coil does not operate.

### SUMMARY OF THE INVENTION

Embodiments of the present application provide a magnetic resonance system, and a head coil for the magnetic resonance system. The head coil comprises a coil support body defining a cavity for accommodating the head of a subject; and a coil unit disposed on the coil support body, the coil unit comprising: a first end ring; a second end ring, the centers of the first end ring and the second end ring being opposite to each other, and the inner diameter of the second end ring being less than the inner diameter of the first end ring; and a plurality of conductive portions connecting the first end ring and the second end ring, each of the conductive portions comprising a first extension portion extending from the first end ring along a first direction, and a second extension portion extending from the second end ring along a second direction, wherein the first direction is parallel to the axial directions of the first end ring and the second end ring, and the second direction is at an angle to the first direction.

According to another aspect of the embodiments of the present application, provided is a magnetic resonance system, comprising: a body coil; and the head coil according to the above aspect, the coil unit of the head coil being used to be wirelessly coupled to the body coil to receive a radio frequency pulse transmitted via the body coil, and amplify the radio frequency pulse to excite the head of the subject accommodated in the cavity of the coil support body.

With reference to the following description and drawings, specific implementations of the embodiments of the present application are disclosed in detail, and the way in which the principles of the embodiments of the present application can be employed are illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of a structure of a body coil and a radio frequency local coil according to an embodiment of the present application;

FIG. 3 is a schematic diagram of a structure of the head coil according to an embodiment of the present application;

FIG. 4 is a schematic diagram of a structure of the coil unit in FIG. 3;

FIG. 5 is an electrical structure diagram of the coil unit in FIG. 4;

FIGS. 6 and 7 are schematic diagrams of a structure of a head coil according to another embodiment of the present application;

FIG. 8 is a schematic diagram of a structure of the base and the headrest in FIG. 6;

FIGS. 9 and 10 each show images generated by imaging a test water phantom using a conventional coil; and

FIG. 11 shows an image generated by imaging a test water phantom using a head coil according to an embodiment of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc. are used to distinguish between different elements in terms of appellation, but do not represent a spatial arrangement, a temporal order, or the like of these elements, and these elements should not be limited by these terms. The term “and/or” includes any one of and all combinations of one or more associated listed terms. The terms “include”, “comprise”, “have”, etc. refer to the presence of described features, elements, components, or assemblies, but do not exclude the presence or addition of one or more other features, elements, components, or assemblies.

In the embodiments of the present application, the singular forms “a”, “the”, etc., include plural forms, and should be broadly construed as “a type of” or “a class of” rather than being limited to the meaning of “one”. Furthermore, the term “the” should be construed as including both the singular and plural forms, unless otherwise explicitly specified in the context. In addition, the term “according to” should be construed as “at least in part according to . . . ” and the term “based on” should be construed as “based at least in part on . . . ”, unless otherwise specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

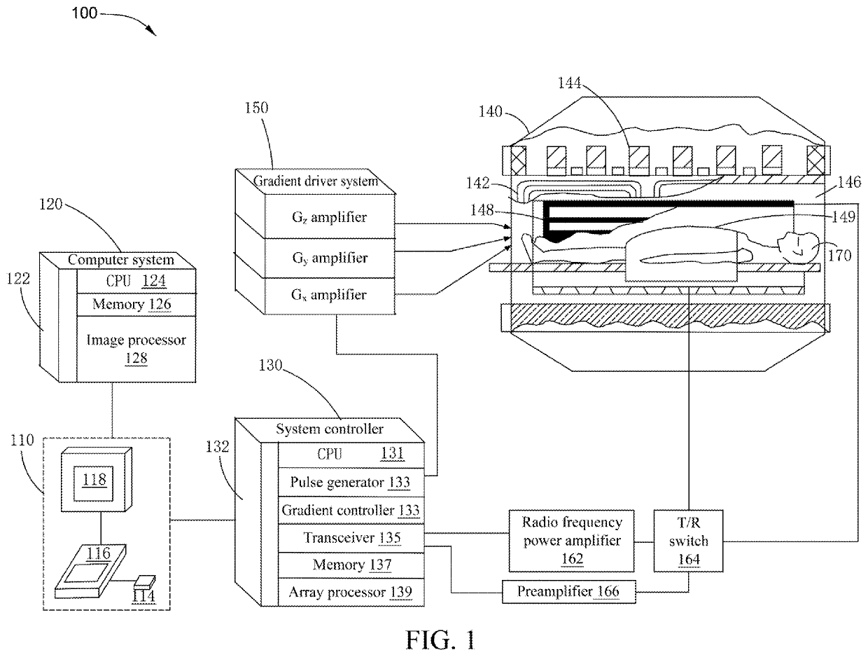

For ease of understanding, FIG. 1 shows a magnetic resonance system 100 according to some embodiments of the present invention.

The MRI system 100 comprises a scanning unit 140. A subject or patient 170 of MRI scan may be located in the scanning unit 140, specifically within a cylindrical imaging volume 146. The scanning unit 140 is used to perform a magnetic resonance scan on the subject 170, to generate image data of a region of interest of the subject 170. The region of interest may be a predetermined anatomical site or anatomical tissue.

The scanning unit 140 comprises a superconducting magnet having a superconducting coil 144 that, in operation, provides a static uniform longitudinal magnetic field B₀ throughout the cylindrical imaging volume 146. The scanning unit 140 further comprises a gradient coil assembly 142 and a body coil 148. The body coil 148 provides a transverse magnetic field B₁ in operation. The transverse magnetic field B₁ is approximately perpendicular to B₀ in the entire cylindrical imaging volume 146, and is used to excite excited nuclei in the body of the subject 170, to generate an MR signal. The gradient coil assembly 142 may be used to provide gradient magnetic fields in, for example, three directions (X, Y, and Z) for superposition on a B₀ field, and provide position encoding of the MR signal.

The body coil 148 may be configured to provide the transverse magnetic field B₁ in a transmit mode, and receive the MR signal in a receive mode. Specifically, the body coil 148 may be configured by a transmit/receive switch (T/R switch) 164 to operate in the transmit mode or the receive mode. The T/R switch 164 may be controlled by a signal from a system controller 130 to electrically connect, during the transmit mode, a radio frequency power amplifier 162 to the body coil 148, and to connect, during the receive mode, a preamplifier 166 to the body coil 148. However, to improve the image signal-to-noise ratio, the body coil 148 may also be decoupled during the receive mode, and the preamplifier 166 may be connected to a surface coil 149 to receive the MR signal using the surface coil 149.

However, to improve the image signal-to-noise ratio, a radio frequency local coil (not shown) may be further provided. A transmit coil may be provided in the radio frequency local coil to replace the body coil, the radio frequency local coil performing radio frequency excitation only on a local site of the subject. The radio frequency local coil is typically disposed on a movable table carrying the subject, and is connected to the radio frequency power amplifier by means of a cable passing through the movable table to receive a radio frequency power signal in the transmit mode and generate the B₁ field, at which time the body coil 148 does not operate. A receive coil may also be provided in the radio frequency local coil, and the radio frequency local coil is connected to the preamplifier 166 when switched to the receive mode, so as to transmit the received MR signal to the preamplifier 166.

Operation of the MRI system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118.

The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate system controller 130.

The system controller 130 includes a set of components that communicate with one another by means of an electrical and/or data connection module 132. The connection module 132 may employ a direct wired connection, a fiber optic connection, a wireless communication link, etc. The system controller 130 may include a CPU 131, a pulse generator 133, a transceiver (or an RF transceiver) 135, a memory 137, and an array processor 139. In some embodiments, the pulse generator 133 may be integrated into the scanning unit 140 of the magnetic resonance system 100.

The system controller 130 may receive a command from the operator workstation 110 to indicate a scan sequence that is to be executed during a magnetic resonance scan performed on the subject 170. The “scan sequence” above refers to a combination of pulses that have specific intensities, shapes, timings, and the like applied during the execution of a magnetic resonance scan. The pulses may typically include, for example, a radio frequency pulse and a gradient pulse. A plurality of scan sequences may be pre-stored in the computer system 120, so that a sequence suitable for clinical examination requirements can be indicated by means of the operator workstation. The clinical examination requirements may include, for example, an imaging site, an imaging function, an imaging effect, scanning safety, and the like. The pulse generator 133 of the system controller 130, based on the indicated sequence, sends an instruction describing the timings, intensities, and shapes of a radio frequency pulse and a gradient pulse in the sequence, so as to operate a system component that executes the sequence.

A radio frequency pulse in the scan sequence sent by the pulse generator 133 may be generated by the transceiver 135, and the radio frequency pulse is amplified by a radio frequency power amplifier 162. The amplified radio frequency pulse is provided to the radio frequency transmit coil, such as the body coil 148 or the radio frequency local coil, by means of the transmit/receive switch (T/R switch) 164, and the radio frequency transmit coil then immediately provides the transverse magnetic field B₁. As a non-limiting example, a transmitting portion in the transceiver 135, the radio frequency power amplifier 162, the T/R switch 164, and the like constitute at least a portion of a radio frequency transmit link.

The system controller 130 also provides gradient waveforms to a gradient driver system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in the gradient coil assembly 142, to generate a magnetic field gradient used to spatially encode an MR signal during a magnetic resonance scan. The X direction may also be referred to as a frequency encoding direction or a kx direction in K-space. The Y direction may be referred to as a phase encoding direction or a ky direction in the K-space. The Z direction is the slice selection direction. Gₓ may be used for frequency encoding or signal readout, and is generally referred to as a frequency encoding gradient or a readout gradient. G_{y} may be used for phase encoding, and is generally referred to as a phase encoding gradient. G_{z} may be used for slice (layer) position selection to obtain k-space data. It should be noted that a layer selection direction, a phase encoding direction, and a frequency encoding direction may be modified according to actual requirements.

In some embodiments, the MR signal sensed and received by the coil and amplified by the preamplifier 166 is demodulated, filtered, and digitized in a receiving portion of the transceiver 135, and transmitted to the memory 137 in the system controller 130. For each image that is to be reconstructed, the data is rearranged into a separate k-space data array, each of the separate k-space data arrays is inputted into the array processor 139, and the array processor is operated to transform the data into an array of image data by means of a Fourier transform.

The array processor 139 uses transform methods, most commonly a Fourier transform, to reconstruct images from the received magnetic resonance signal. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the system controller 130 may be implemented on the same computer system or on a plurality of computer systems. The system controller 130 and the image processor 128 may separately or collectively include a computer processor and a storage medium. The storage medium has recorded thereon a program that is for predetermined data processing and that is to be executed by the computer processor. For example, the storage medium may have stored thereon a program used to implement scanning processing (such as a scan flow, and an imaging sequence), image reconstruction, image processing, and the like. The above storage medium may include, for example, a ROM, a floppy disk, a hard disk, an optical disk, a magneto-optical disk, a CD-ROM, or a non-volatile memory card.

It should be understood that the magnetic resonance system 100 shown in FIG. 1 is intended for illustration. A suitable magnetic resonance system may include more, fewer, and/or different components.

As described above, the body coil 148 may be used to transmit a radio frequency signal and to receive a magnetic resonance signal, although in general a local coil (such as a receive coil in a radio frequency local coil or a surface coil) may also be employed to receive a magnetic resonance signal. The local coil is typically positioned close to the patient and thus provides a higher signal-to-noise ratio (SNR).

At present, a common local coil adopts a phased array coil composed of a plurality of coil components. Each type of local coil needs to be equipped with a respective cable and receive channel for transmitting a magnetic resonance signal. The local coil has a cable interface for connecting to one end of the cable. The other end of the cable is connected to a cable interface disposed on an examination table. A magnetic resonance signal received from the local coil is transmitted to a receive chain module of the local coil through the cable, amplified by a radio frequency preamplifier, then demodulated, filtered, analog-to-digital converted, pre-processed, Fourier transformed and so on, and finally reconstructed into a magnetic resonance image.

The phased array coil typically includes a decoupling circuit. In some embodiments, the decoupling circuit may be used for electromagnetic decoupling between the receive coil and the radio frequency transmit coil during radio frequency transmission to avoid affecting the transmit field.

A decoupling circuit included in the phased array coil requires DC power to operate, so the coil array also needs to rely on cables for DC power supply, but this increases the difficulty in wiring. In addition, to improve the image quality, the number of receive channels is increasing. For example, the number of receive channels is 16 or 32 or 64 or the like, which undoubtedly further increases the complexity of the cable interface and the cable and increases costs.

Although some local coils are also capable of transmitting a radio frequency excitation signal and receiving an MR signal (switchable between the transmit mode and the receive mode), in addition to requiring the receive cable, the receive channel, and the decoupling circuit described above, the local coils further need to be electrically connected to the radio frequency transmit link via an additional cable (e.g., disposed on or passing through a patient table that supports the subject) to receive a radio frequency excitation pulse from the radio frequency transmit link. This also increases the difficulty of wiring. In addition, the electrical structure of such a local coil is typically disposed on a hard material.

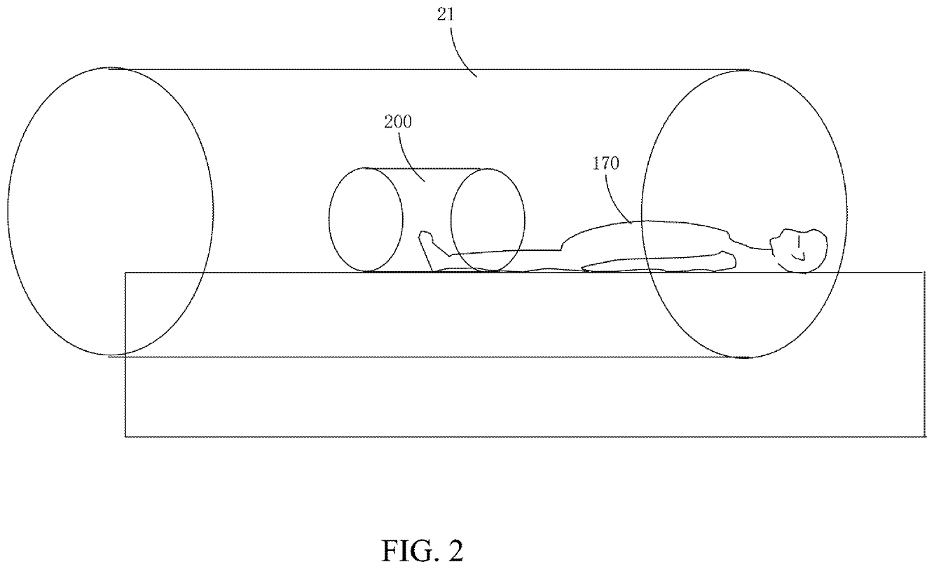

In view of at least one of the above technical problems, at least some of the inventors of the present application propose a radio frequency local coil that can be coupled in a magnetic resonance system in a cable-free manner. FIG. 2 shows a schematic diagram of a structure of an embodiment of the radio frequency local coil 200. The radio frequency local coil 200 is used to couple to a body coil 21 (for example, a body coil 148 in FIG. 1) of a magnetic resonance system to receive a radio frequency pulse transmitted from the body coil, so as to generate a radio frequency field exciting the subject 170. The radio frequency local coil further sends, to the body coil, a magnetic resonance signal received from the object 170, thereby implementing a magnetic resonance scan performed on the region to be scanned of the object 170.

In some embodiments, the radio frequency local coil 200 has an electromagnetic structure similar to that of the body coil 21, for example, a birdcage-like structure. Also, during scanning, the radio frequency local coil 200 is disposed in a scanning space defined by the body coil 21. The radio frequency local coil at least partially surrounds a site to be scanned of the subject, i.e., the radio frequency local coil is located between the body coil 21 and the subject. In other words, the radio frequency local coil is closer to the subject than the body coil 21.

In some embodiments, a transmit chain module of the magnetic resonance system generates a digital pulse waveform according to a specified scan sequence, and converts the digital pulse waveform into an analog signal. The analog signal is amplified by a radio frequency amplifier and transmitted to the body coil 21 by means of a transmission cable, to drive the body coil 21 to transmit a radio frequency excitation pulse.

The principles of electromagnetism are employed such that, during scanning, the radio frequency local coil is close to the body coil, so as to generate electromagnetic coupling, which is strong. Therefore, when the body coil 21 transmits a radio frequency pulse, a current may be induced in the radio frequency local coil 200, that is, the radio frequency pulse may be transferred from the body coil 21 to the radio frequency local coil 200 by using the induced magnetic field. The radio frequency pulse transferred to the radio frequency local coil 200 generates a uniform magnetic field B1, and excites the site to be scanned of the subject to generate resonance, so as to generate a transverse magnetization vector. After the transmission of the radio frequency pulse is completed (after the magnetic field B1 is removed), the site of the subject 170 covered by the radio frequency local coil 200 produces a magnetic resonance signal. The magnetic resonance signal is sensed and received by the radio frequency local coil 200. Similarly, when the radio frequency local coil 200 receives the magnetic resonance signal, a current may be induced in the body coil 21, that is, the magnetic resonance signal may be transferred from the radio frequency local coil 200 to the body coil 21 by using the induced magnetic field, and be transmitted to a receive chain module of the system by means of a transmission cable connected to the body coil 21, and reconstructed into a magnetic resonance image after processing.

Thus, the radio frequency local coil 200 implements self-transmission and self-reception of a radio frequency signal. A magnetic resonance scan on a local site of the subject may be implemented using only the receive link and the transmit link of the system connected to the body coil 21 without: providing DC power for switching the transmit/receive modes, disposing a decoupling circuit in the conventional coil array structure, or disposing an additional receive chain module and/or a transmit chain module (for example, disposing a receive chain module and/or a transmit chain module corresponding to the conventional coil array).

On one hand, the wiring problem of the magnetic resonance system can be simplified, simplifying the circuit structure, improving reliability, reducing a failure rate, reducing costs, and facilitating picking and placement. On the other hand, a lower Specific Absorption Rate (SAR) and a higher Signal-to-Noise Ratio are achieved.

However, the inventors of the present application have further found that, when the above technology is applied to head (or brain, Head) imaging, even if the head coil is designed with an electromagnetic structure similar to that of the body coil (e.g., birdcage-like), and signal excitation and reception are performed using electromagnetic coupling between the head coil and the body coil, it is still difficult to achieve a desired clinical effect. For example, there are image quality issues in some aspects, or it is difficult to achieve expected imaging quality for a specific region of the head.

In view of at least one of the above technical problems, embodiments of the present application provide a head coil for a magnetic resonance system.

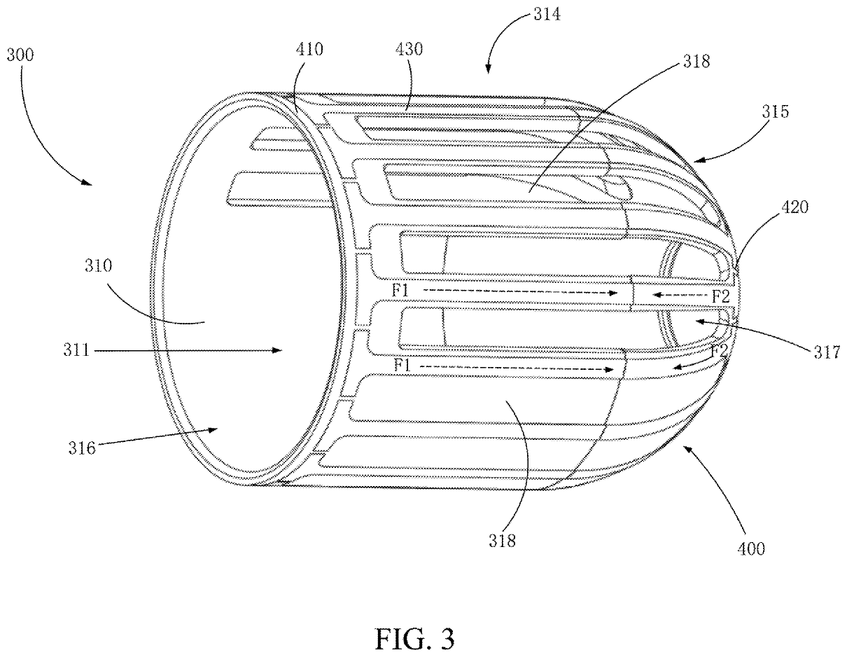

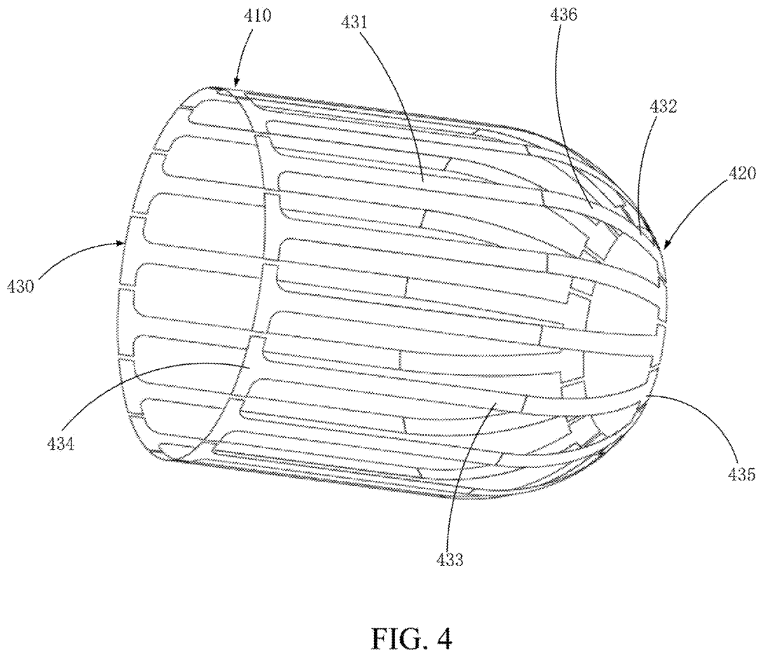

FIG. 3 is a schematic diagram of a structure of a head coil 300 according to an embodiment of the present application, which includes a coil support body 310 and a coil unit 400. FIG. 4 is a schematic diagram of a structure of the coil unit 400. Referring to FIGS. 3 and 4, the coil support body 310 defines a cavity 311 for accommodating the head of a subject. The coil unit 400 is disposed on the coil support body 310. In some embodiments, the coil unit may be disposed around the cavity 311 of the coil support body 310, so that when the head of the subject is located in the cavity 311, a region of interest in the head can be located within a space formed by the coil 400. Specifically, the coil unit 400 may be disposed on an outer surface or an inner surface of the coil support body 310, or between the inner and outer surfaces.

The coil unit 400 includes a first end ring 410 and a second end ring 420. The centers of the first end ring 410 and the second end ring 420 are opposite to each other, and the inner diameter of the second end ring 420 is less than the inner diameter of the first end ring 410.

The coil unit 400 further includes a plurality of conductive portions 430 connecting the first end ring 410 and the second end ring 420. Each of the conductive portions 430 includes a first extension portion 431 extending from the first end ring 410 in a first direction F1 and a second extension portion 432 extending from the second end ring 420 in a second direction F2. The first direction F1 is parallel to the axial directions of the first end ring 410 and the second end ring 420, e.g., parallel to the direction of a line connecting the centers of the first end ring 410 and the second end ring 420. The second direction F2 is at an angle to the first direction F1. For example, the second extension portion 430 of each of the conductive portions 430 extends obliquely relative to the axial directions of the first end ring 410 and the second end ring 420. The angle of the described obliqueness may be set based on the contour structure of the top of the human head, for example, to enable the second extension portion to be closer to the top of the human head.

The head coil according to the embodiment of the present application, by providing the opposing first and second end rings and the plurality of conductive portions connecting the two end rings, and having the conductive portions extend parallel to the axial direction at one end of the head coil, enables the coil unit to maintain a high degree of coupling with the body coil when in cable-free connection. This allows for amplification of radio frequency emission signals from the body coil to generate a uniform B1 field in the brain region of the head coil, and amplification of magnetic resonance signals from the brain region for return to the body coil. Meanwhile, the embodiments of the present application are not confined to the notion that “the closer the electrical structure of a radio frequency local coil is to that of the body coil, the better the image quality will be.” Instead, the birdcage-like structure is deformed such that one end of the head coil (e.g., at the second end ring) has a smaller inner diameter than the other end (e.g., at the first end ring). Furthermore, at the end with the smaller inner diameter, the conductive portions between the end rings do not extend parallel to the axial direction. This enables the top and side of the head to fit the coil unit more closely when the head of the subject is positioned inside the head coil. Consequently, during brain imaging, a higher signal-to-noise ratio can be achieved at the center of the brain, thereby improving image quality.

In some embodiments, the length of the first extension portion 431 of each conductive portion 430 is greater than the length of the corresponding second extension portion 432, thereby enhancing the degree of coupling with the body coil when used for magnetic resonance imaging.

The second direction F2 may be a linear direction or a curved direction. That is to say, the second extension portion 431 may be inclined relative to the first direction and extend along another linear direction, or the second extension portion 431 may be entirely curved so as to form a smooth transition with the first extension portion, or the second extension portion 431 may be partly linear and partly curved.

With continued reference to FIG. 4, each conductive portion 430 further includes a curved transition portion 436 located between the first extension portion 431 and the second extension portion 432. For example, the conductive portion 430, starting from the first end ring 410, extends parallel to the axial direction for a certain length, and then forms the curved transition portion 436 through a curved bend. This enables a smooth transition toward the second end ring 420, thereby improving structural reliability and facilitating smooth signal transmission.

The centerlines of the first extension portion 431 and the second extension portion 432 along the length directions thereof can both be projected onto the central axis of the coil unit 400. In this way, structural symmetry is ensured, which contributes to improving the coupling performance of the coil unit 400 with the body coil.

In some embodiments, the plurality of conductive portions 430 are connected to the first end ring 410 at equal first intervals and are connected to the second end ring 420 at equal second intervals, the first interval being greater than the second interval. This helps achieve a high degree of coupling with the body coil, and produce a uniform radio frequency excitation field.

Thus, the plurality of conductive portions of the head coil according to the embodiments of the present application can be evenly distributed along the two end rings, and converge uniformly towards the second end ring 420 in the vicinity of the second end ring 420, resulting in one end of the head coil forming a domed shape. This is beneficial for achieving better image quality when imaging head tissues (e.g., the brain) near the top and side of the head.

Referring to FIG. 4, in some embodiments, each conductive portion 430 may include an axial portion 433 extending along the axial direction. At both ends of the axial portion 433, a first circumferential extension portion 434 and a second circumferential extension portion 435, which are integrally formed with the axial portion 433, may each be included. The first circumferential extension portion 434 and the second circumferential extension portion 435 are each formed together with the shaft portion 433 as a substantially “T” shaped structure. The first circumferential extension portions 434 of the plurality of conductive portions 430 are sequentially spaced apart to form the first end ring 410, and the second circumferential extension portions 435 of the plurality of conductive portions 430 are sequentially spaced apart to form the second end ring 420.

The first end ring 410, the second end ring 420, and the plurality of conductive portions 430 may be made of copper foil or other materials having good electrical conductivity. The first end ring 410, the second end ring 420, and the plurality of conductive portions 430 may be formed on the coil support body by means of a circuit board printing process or other process techniques.

In the embodiments of the present application, the coil support body for disposing the coil unit 400 includes a first end portion and a second end portion, and the cavity 311 is disposed between the first end portion and the second end portion. Specifically, the coil support body 310 may include a cylindrical portion 314 and a dome-shaped portion 315, the cylindrical portion 314 and the dome-shaped portion 315 being in communication via the cavity 311. One end of the cylindrical portion 314 forms the first end portion of the coil support body 310, which is used for disposing the first end ring 410 of the coil unit 400 thereon. The dome-shaped portion 315 is formed by extending from the other end of the cylindrical portion 314 with a gradually narrowing inner diameter. An end of the dome-shaped portion 315 distant from the cylindrical portion 314 forms the second end portion of the coil support body 310, which is used for disposing the second end ring 420 of the coil unit 400 thereon.

The cross-sections of the cylindrical portion and the dome-shaped portion are preferably circular, but may also be polygonal. The number of sides of the polygon may be, for example, the same as the number of the conductive portions 430.

Similarly, the cavity 311 formed in the coil support body 310 correspondingly has a cylindrical cavity wall and a dome-shaped cavity wall.

In some embodiments, a main body portion of the coil support body 310, for example, a portion for supporting the coil unit 400, has a uniform thickness, which allows the inner surface and the outer surface of the support body 310 to have similar contour trajectories. While matching the shape of the human head, this configuration maintains a uniform and sufficiently small distance between the coil unit 400 and the subject's head, thereby improving the image uniformity and the signal-to-noise ratio.

A first opening 316 communicating with the cavity is provided at the first end portion of the coil support body 310. When the head coil according to the embodiment of the present application is in use, the head of the subject enters and exits the cavity 311 through the first opening 316. Further, a second opening 317 may be provided along the second end portion 315 of the coil support body 31. When the head coil is fitted over the human head, the second opening 317 provides air circulation and an external field of view, thereby improving the comfort of the subject and the convenience of positioning.

In other embodiments, the second end portion of the coil support body 31 may not be provided with the second opening 317, but may instead form a closed structure.

In the embodiments of the present application, the dimensions of the cavity 311, the first end portion, the second end portion, the first opening 316 and the second opening 317 of the coil support body 310, and the first end ring 410, the second end ring 420 and the first extension portions and the second extension portions of the conductive portions 430 of the coil unit may be designed with reference to the dimensions of the human head.

Further, the coil support body 310 includes a plurality of through holes 318 disposed between the first end portion and the second end portion and communicating with the cavity 311. Specifically, the through holes 318 may be formed on the coil support body 310 at positions between adjacent conductive portions, to improve the comfort of the subject and the convenience of positioning, provide an internal field of view and communication convenience for the subject, and alleviate discomfort caused by claustrophobia. The through holes 318 may be provided on one side of the coil support body 310, for example, for facing the facial region of the subject. In some embodiments, a region where the through holes 318 are located may include the upper half or even more of the coil support body 310. The number of groups of the through holes 318 may be approximately half the number of channels of the coil unit. For example, one group of through holes may be provided between every two adjacent conductive portions in the upper half of the coil support body 310. The number of through holes in each group may be one or more. Taking a 16-channel coil as an example, the number of groups of the through holes 318 may be eight.

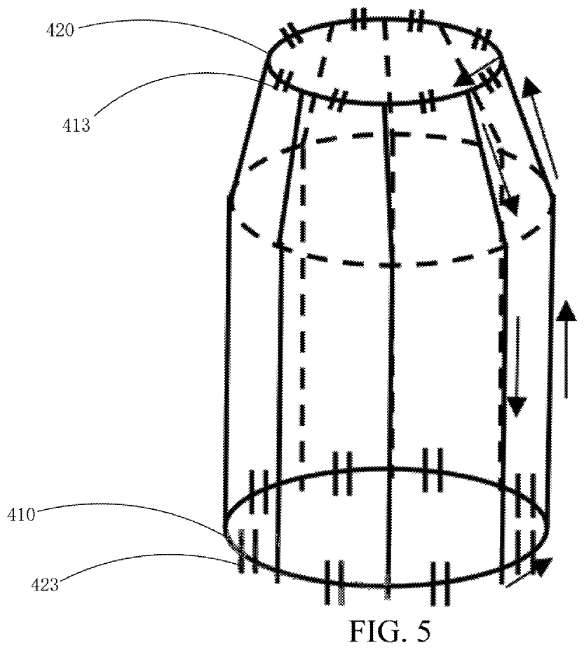

FIG. 5 shows an electrical structure diagram of the coil unit in FIG. 4. Referring to FIG. 4 and FIG. 5, a plurality of first capacitors 413 are disposed on the first end ring 410 at the first intervals, and a plurality of second capacitors 423 are disposed on the second end ring 430 at the second intervals. The plurality of conductive portions 430 are separately connected to the plurality of first capacitors 413 and the plurality of second capacitors 423. In some embodiments, both ends of each first capacitor 413 are connected to one end of two adjacent conductive portions located on the first end ring 410, respectively. Similarly, both ends of each second capacitor 423 are connected to one end of two adjacent conductive portions 430 located on the second end ring 420, respectively.

In some embodiments, to improve the stability of the electrical structure and the accuracy of signal control, the first capacitors 413 and the second capacitors 423 are all lumped capacitors. The first capacitor 413 and 423 may be soldered onto the first end ring 410 and the second end ring 420, respectively. For example, each first capacitor 413 connects two adjacent first circumferential extension portions 434, and each second capacitor 423 connects two adjacent second circumferential extension portions 435.

However, in consideration of different performance requirements or application scenarios, the first capacitor 413 and the second capacitor 423 may also be designed as distributed capacitors.

The direction of arrows in FIG. 5 indicates the flow direction of the coupling current generated on the coil unit 400 when the head coil is wirelessly coupled to the body coil. The flowing current generates a radio frequency excitation signal in an X-Y plane of the magnetic resonance system, i.e., generates a radio frequency excitation field (B1 field) for exciting the head tissue of the subject. Also, when the body coil is in the receive mode, the magnetic resonance signal generated by the head tissue is transmitted to the body coil via the wireless coupling path between the coil unit 400 and the body coil.

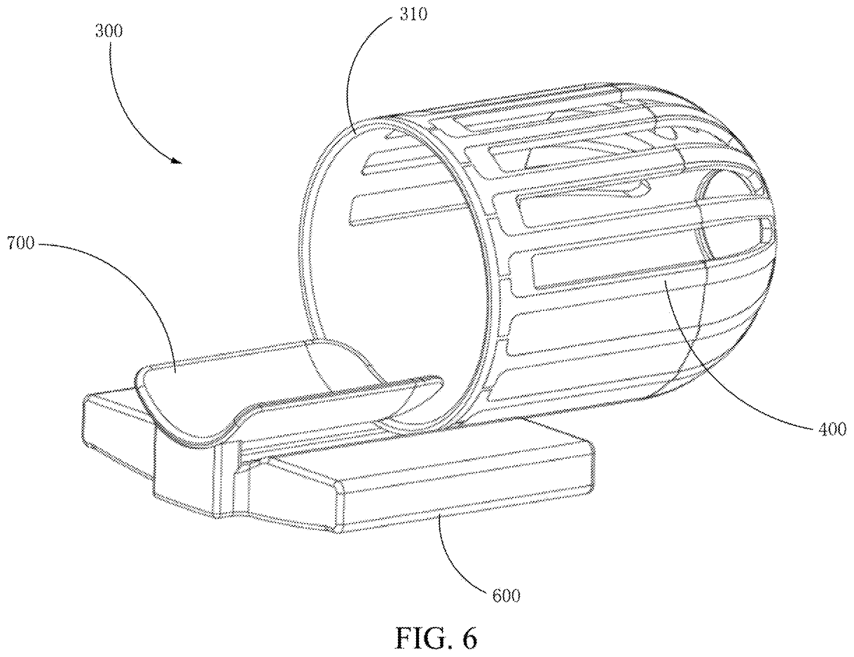

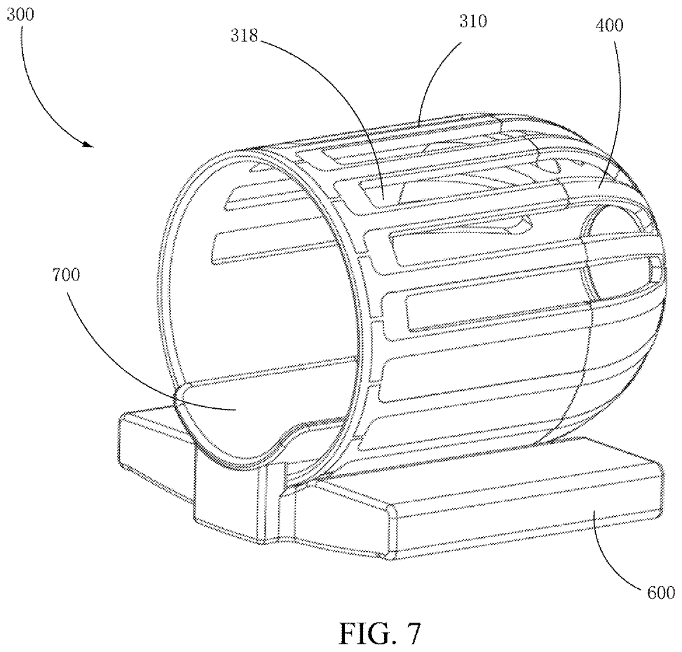

FIGS. 6 and 7 show schematic diagrams of a structure of a head coil according to another embodiment of the present application. The head coil further includes a base 600 used to secure the coil support body 310 and a headrest 700 connected to the base. FIG. 8 shows a schematic diagram of a structure of the base 600 and the headrest 700. Referring to FIG. 6, FIG. 7, and FIG. 8, the base 600 includes a recess 610 used to mate with the coil support body 310. The recess 610 may be used to guide the coil support body 310 to be installed on the base 600 or to be separated from the base 600. Moreover, when the coil support body 310 is installed on the base 600, the recess 610 provides positional constraint to the coil support body 310. In the embodiments of the present application, the recess 610 has a curvature matching an outer surface of the bottom of the coil support body 310. The bottom of the coil support body 310 is opposite to the plurality of through holes 318. Specifically, an outer side wall of the bottom of the coil support body 310 may be opposite to the occipital region of the subject, and an inner side wall thereof is opposite to the through holes 318.

The headrest 700 is located above the recess 610 of the base 600, and a gap 710 is defined between the headrest and the recess 610. The gap 710 is used to accommodate the bottom of the coil support body 310, to further provide positional constraint and installation guidance for the coil support body 310.

Specifically, the headrest 700 includes a fixed end 720 configured to be secured to the base 600 and a free end 730 opposite to the fixed end 720. The gap 710 may extend from the free end 730 of the headrest 700 toward the fixed end 720, to provide a sliding path for the coil support body 310.

The headrest 700 is used to support the head of the subject. Moreover, in the embodiment of the present application, the base 600 and the headrest 700 may be installed on a scanning table of the magnetic resonance system. Before a magnetic resonance scan is performed, when the subject lies supine and places the head on the headrest 700, an operator may further install the coil support body 310, for example, by aligning the bottom of the coil support body 310 with the gap 710 between the base 600 and the headrest 700, as shown in FIG. 6. The coil support body then slides along the gap 710 and is finally positioned above the base 600 to cover the head of the subject, as shown in FIG. 7. Such a design ensures stable and accurate positioning of the head of the subject, thereby improving scanning quality and effectiveness. In other embodiments, the coil support body 310 may also be directly fixed to the base, and the subject actively inserts the head into the coil support body 310 while lying supine on the scanning table.

In the embodiments of the present application, a track 611 may be provided on the surface of the recess 610 of the base 600. The track 611 is used to cooperate with the coil support body 310 so that the coil support body 310 can slide along the track 611 into the gap 710 to cover the head of the subject, for example, to allow the head of the subject to enter the cavity 311 of the coil support body 310 from the first opening 316 of the coil support body 310. Although not shown in the figures, a sliding member cooperating with the track 611 may be provided on the outer surface of the coil support body 310, to achieve more precise positioning and easier operation.

The components such as the coil support body, the base, and the head support may be made of resin or other suitable materials.

As described above, the head coil according to any embodiment of the present application may be used for a magnetic resonance system. The magnetic resonance system further includes a body coil. The coil unit of the body coil is used to be wirelessly coupled to the body coil to receive a radio frequency pulse transmitted via the body coil and amplify the radio frequency pulse to excite the head of the subject accommodated in the cavity of the coil support body.

The embodiments of the present application may further provide a magnetic resonance system, including a body coil and the head coil according to any one of the above embodiments. The coil unit of the head coil is used to be wirelessly coupled with the body coil to receive a radio frequency pulse transmitted via the body coil, and amplify the radio frequency pulse to excite the head of the subject to be scanned accommodated in the cavity of the coil support body.

The embodiments of the present application may further provide a magnetic resonance imaging method, comprising: using wireless coupling between a head coil, placed within a scanning space defined by a body coil, and the body coil, to receive a radio frequency pulse transmitted via the body coil, and amplifying the radio frequency pulse to excite the head of a subject accommodated in a cavity of a coil support body.

The method further comprises: using wireless coupling between the head coil and the body coil, receiving a magnetic resonance signal generated by the head of the subject, and transmitting the magnetic resonance signal to the body coil.

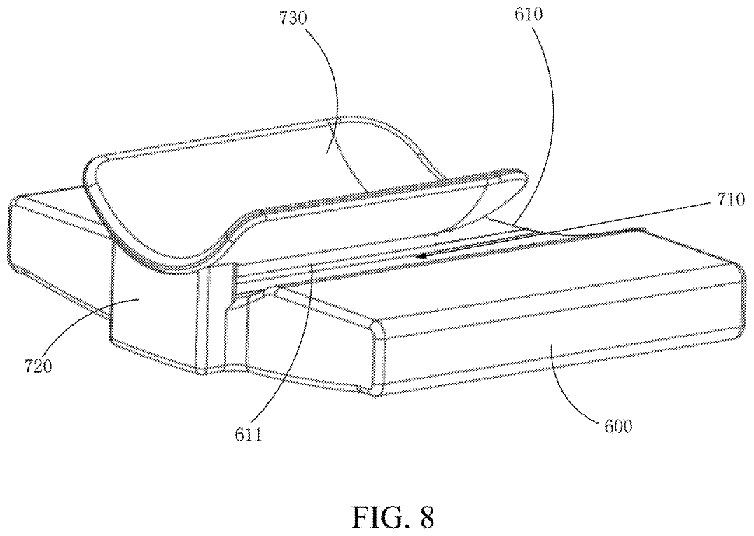

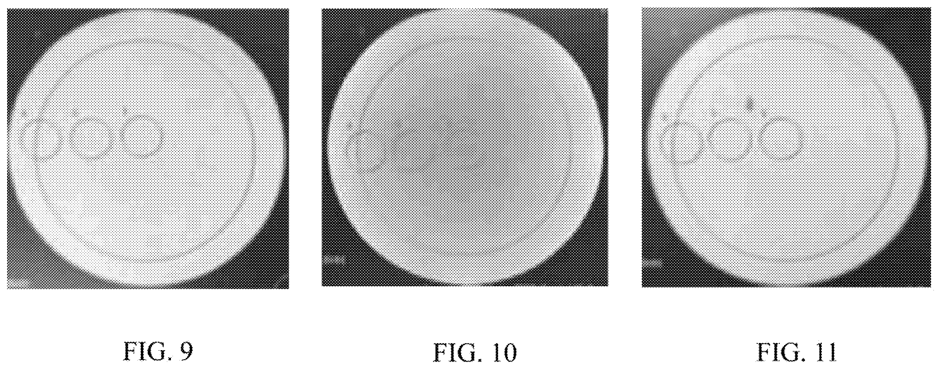

FIG. 9 and FIG. 10 each show images generated by imaging a test water phantom using a conventional coil. The example in FIG. 9 is an image of a body coil generated by directly exciting the water phantom using the body coil and directly receiving a magnetic resonance signal produced by the water phantom. The example in FIG. 10 is an image of a surface coil generated by directly exciting the water phantom using the body coil and receiving the magnetic resonance signal produced by the water phantom using a conventional surface receive coil. FIG. 11 shows an image generated by imaging a test water phantom using a head coil according to an embodiment of the present application. As can be seen from the comparison among FIGS. 9 to 11, when imaging is performed using the head coil according to the embodiments of the present application, the image uniformity is as good as that of the image of the body coil. Moreover, the signal-to-noise ratio in the central region and the 20% region of the region of interest is far higher than that of the image of the body coil, and is even close to that of an image of a surface coil. Furthermore, compared to conventional imaging methods, when imaging is performed using the head coil according to the embodiments of the present application, the required transmit power is significantly reduced (for example, the TG value decreases from approximately 140 to approximately 35), thereby reducing the specific absorption rate (SAR) borne by the subject, saving energy for magnetic resonance scanning, and improving scanning safety.

The above embodiments merely provide illustrative descriptions of the embodiments of the present application. However, the present application is not limited thereto, and suitable variations may be made on the basis of the above embodiments. For example, each of the above embodiments may be used independently, or one or more of the above embodiments may be combined.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for executing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A head coil for a magnetic resonance system, comprising:
a coil support body defining a cavity for accommodating the head of a subject; and
a coil unit disposed on the coil support body, the coil unit comprising:
a first end ring;
a second end ring, the centers of the first end ring and the second end ring being opposite to each other, and the inner diameter of the second end ring being less than the inner diameter of the first end ring; and
a plurality of conductive portions connecting the first end ring and the second end ring, each of the conductive portions comprising a first extension portion extending from the first end ring along a first direction, and a second extension portion extending from the second end ring along a second direction, wherein the first direction is parallel to the axial directions of the first end ring and the second end ring, and the second direction is at an angle to the first direction.

2. The head coil according to claim 1, wherein the length of the first extension portion of each of the conductive portions is greater than the length of the corresponding second extension portion.

3. The head coil according to claim 1, wherein each of the conductive portions comprises a curved transition portion located between the first extension portion and the second extension portion.

4. The head coil according to claim 1, wherein the plurality of conductive portions are connected to the first end ring at equal first intervals and are connected to the second end ring at equal second intervals, the first interval being greater than the second interval.

5. The head coil according to claim 4, wherein a plurality of first capacitors are disposed on the first end ring at the first intervals, a plurality of second capacitors are disposed on the second end ring at the second intervals, and the plurality of conductive portions are separately connected to the plurality of first capacitors and the plurality of second capacitors.

6. The head coil according to claim 1, wherein the coil support body comprises a first end portion and a second end portion, the cavity is disposed between the first end portion and the second end portion, and a first opening in communication with the cavity is provided at the first end portion, the first end ring is disposed along the first end portion, and the second end ring is disposed along the second end portion.

7. The head coil according to claim 6, wherein a second opening is provided at the second end portion.

8. The head coil according to claim 6, wherein the coil support body comprises a plurality of through holes disposed between the first end portion and the second end portion and communicating with the cavity.

9. The head coil according to claim 8, further comprising:
a base used to secure the coil support body, the base defining a recess used to mate with the coil support body; and
a headrest connected to the base, the headrest being used to support the head of the subject, the headrest being disposed above the recess with a gap defined therebetween, and the gap used configured to accommodate the bottom of the coil support body, wherein the bottom of the coil support body is opposite to the plurality of through holes.

10. The head coil according to claim 9, wherein a track cooperating with the coil support body is provided on a surface of the recess of the base, and wherein the coil support body is capable of sliding along the track into the gap to allow the head of the subject to enter the cavity from the first opening.

11. The head coil according to claim 1, wherein the magnetic resonance system comprises a body coil, and the coil unit of the head coil is used to be wirelessly coupled to the body coil, to receive a radio frequency pulse transmitted via the body coil, and amplify the radio frequency pulse to excite the head of the subject accommodated in the cavity of the coil support body.
